(19) United States
(12) Patent Application Publication
(10) Pub. No.: US 2014/0227442 A1
(43) Pub. Date: Aug. 14, 2014

(54) THIN FILM DEPOSITION DEVICE INCLUDING DEPOSITION-PREVENTING UNIT AND METHOD OF REMOVING DEPOSITS THEREOF

(71) Applicant: SAMSUNG DISPLAY CO., LTD., Yongin-City (KR)

(72) Inventors: Myung-Soo Huh, Yongin-City (KR); Sun-Ho Kim, Yongin-City (KR); Cheol-Rae Jo, Yongin-City (KR); Hyun-Woo Joo, Yongin-City (KR)

(73) Assignee: SAMSUNG DISPLAY CO., LTD., Yongin-City (KR)

(21) Appl. No.: 13/924,456

(22) Filed: Jun. 21, 2013

(30) Foreign Application Priority Data
Feb. 13, 2013 (KR) 10-2013-0015535

(51) Int. Cl. C23C 16/44

(52) U.S. Cl. CPC C23C 16/4407
USPC 427/248.1; 118/715; 134/37; 134/30

(57) ABSTRACT

Provided is a thin film deposition device including a deposition-preventing unit and a method of removing deposits thereof. The method includes: separating a deposition-preventing unit including at least one deposition-preventing plate and a deformation unit coupled to an outer surface of the at feast one deposition-preventing plate from a chamber of the thin film deposition device; and removing a film formation layer from the deposition-preventing plate.

### CROSS-REFERENCE TO RELATED APPLICATION

This application claims priority to and the benefit of Korean Patent Application No. 10-2013-0015535, filed on Feb. 13, 2013, in the Korean Intellectual Property Office, the disclosure of which is incorporated herein in its entirety by reference.

### BACKGROUND

1. Field

Aspects of the present invention relate to a thin film deposition device including a deposition-preventing unit that may easily remove deposits thereon, and a method of removing deposits from the thin film deposition device.

2. Related Art

In general, an organic light-emitting display device including a thin film transistor (TFT) may be used in a display for a mobile device, such as a digital camera, a video camera, a camcorder, a portable information terminal, an ultra-slim notebook computer, a smart phone, a flexible display device, or a tablet personal computer, or may be used in an electrical and electronic product, such as an ultra-slim television.

An organic light-emitting display device may include a first electrode, a second electrode, and an organic light-emitting layer between the first electrode and the second electrode. The organic light-emitting device may include an encapsulation layer that protects the organic light-emitting layer formed on a substrate.

The organic light-emitting layer and the encapsulation layer may be formed using any of a variety of methods. For example, the organic light-emitting layer and the encapsulation layer may be formed by using a deposition method using a thin film deposition device. In this case, a raw material for deposition, such as an organic material, may be deposited not only on a desired area of the organic light-emitting display device in a chamber but also on another area in the chamber.

In order to address this problem, a deposition-preventing plate may be provided in the chamber. However, when film formation is repeatedly performed (e.g., more than 1000 times) by using the raw material for deposition, a film formation layer is formed to a thickness of several millimeters on the deposition-preventing plate. Accordingly, the deposition-preventing plate has to be replaced due to the film formation layer. Also, the film formation layer formed on the thick deposition-preventing layer may exfoliate, thereby generating particles during a deposition process.

### SUMMARY

Embodiments of the present invention provide a thin film deposition device including a deposition-preventing unit that easily removes a film formation layer formed thereon during a deposition process, and a method of removing deposits from the thin film deposition device.

According to an aspect of the present invention, there is provided a thin film deposition device including: a chamber; a deposition unit in the chamber configured to deposit a raw material on a substrate; and a deposition-preventing unit in the chamber including at least one deposition-preventing plate and a deformation unit coupled to one surface of the deposition-preventing plate.

The at least one deposition-preventing plate may include a metal plate.

The deformation unit may include a shape-memory alloy.

The deformation unit may have a wire shape and may contact the one surface of the deposition-preventing plate.

The at least one deposition-preventing plate may include a first deposition-preventing plate and a second deposition-preventing plate, and the deformation unit may be between facing surfaces of the first deposition-preventing plate and the second deposition-preventing plate.

The deformation unit may have a wire shape.

An outer surface of the deformation unit may contact the facing surfaces of the first deposition-preventing plate and the second deposition-preventing plate.

The deposition-preventing unit may be between the chamber and a film formation area where a film formation layer is to be formed.

According to an aspect of the present invention, there is provided a method of removing deposits of a thin film deposition device, the method including: separating a deposition-preventing unit including at least one deposition-preventing plate and a deformation unit coupled to an outer surface of the at least one deposition-preventing plate from a chamber of the thin film deposition device; and removing a film formation layer from the deposition-preventing plate.

The at least one deposition-preventing plate may include a first deposition-preventing plate and a second deposition-preventing plate, and the deformation unit may be between facing surfaces of the first deposition-preventing plate and the second deposition-preventing plate.

The deformation unit may include a shape-memory alloy.

The deformation unit may have a wire shape, and an outer surface of the deformation unit may contact the facing surfaces of the first deposition-preventing plate and the second deposition-preventing plate.

The removing of the film formation layer from the deposition-preventing plate may include: loading the deposition-preventing unit in a constant-temperature bath; separating interfaces between portions of the film formation layer and the deposition-preventing unit; removing the film formation layer from the deposition-preventing unit by using a gas purging process; and extracting the deposition-preventing unit from the constant-temperature bath.

The constant-temperature bath may be maintained at a temperature equal to or higher than a temperature at which the deformation unit is deformed.

The method may further include performing a washing process and a drying process after the extracting of the deposition-preventing unit.

The method may further include: mounting the deposition-preventing unit in the chamber; and depositing a raw material for deposition on a substrate from a deposition unit provided in the chamber.

### BRIEF DESCRIPTION OF THE DRAWINGS

The above and other features and aspects of the present invention will become more apparent by describing in detail exemplary embodiments thereof with reference to the attached drawings in which:

FIG. 1 is a cross-sectional view illustrating a thin film deposition device according to an embodiment of the present invention;

FIG. 2 is a plan view of the thin film deposition device of FIG. 1;

FIG. 3 is a cross-sectional view illustrating a thin film deposition device according to another embodiment of the present invention;

FIG. 4A is a cross-sectional view illustrating a state where a film formation layer is formed on a deposition-preventing unit;

FIG. 4B is a cross-sectional view illustrating a state where the deposition-preventing unit of FIG. 4A is deformed;

FIG. 5 is a flowchart illustrating a process of removing the film formation layer from the deposition-preventing unit; and

FIG. 6 is a cross-sectional view illustrating one sub-pixel of an organic light-emitting display device manufactured by using the thin film deposition device, according to an embodiment of the present invention.

### DETAILED DESCRIPTION

While the invention allows for various changes and numerous embodiments, particular embodiments will be illustrated in the drawings and described in detail in the written description. However, this is not intended to limit the present invention to these particular embodiments, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure features of the invention.

The terms “first,” “second,” “primary,” “secondary,” or the like, as used herein do not denote any order, quantity, or importance, but rather are used to distinguish one element, region, component, layer, or section from another.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “includes,” “including,” “comprises,” and “comprising” used herein specify the presence of stated features, integers, steps, operations, members, components, and/or groups, but do not preclude the presence or addition of one or more other features, integers, steps, operations, members, components, and/or groups.

The present invention will now be described more fully with reference to the accompanying drawings, in which exemplary embodiments of the invention are shown. The same or similar elements are denoted by the same or similar reference numerals.

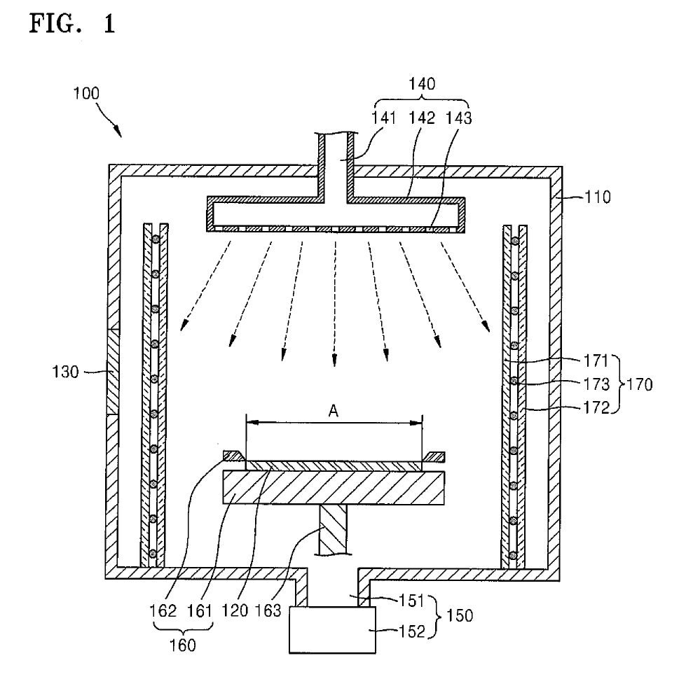

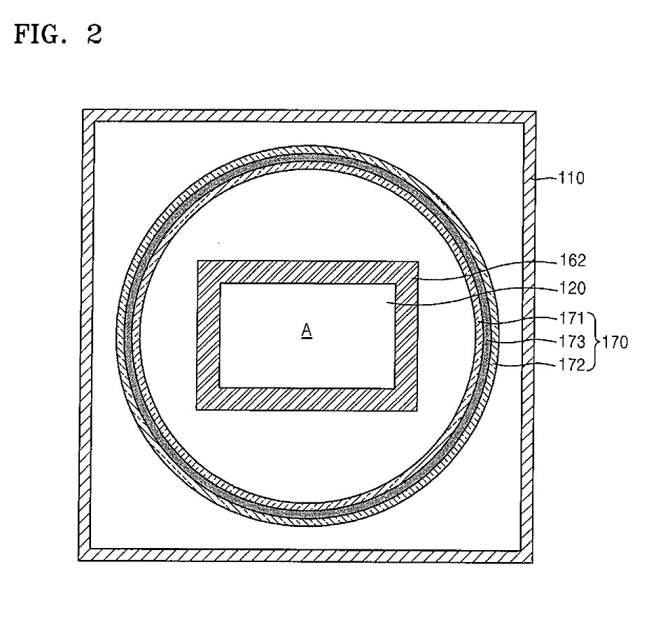

FIG. 1 is a cross-sectional view illustrating a thin film deposition device 100 according to an embodiment of the present invention. FIG. 2 is a plan view illustrating the thin film deposition deice 100 of FIG. 1.

Referring to FIGS. 1 and 2, the thin film deposition device 100 includes a chamber 110. The chamber 110 provides a suitable (or predetermined) space that isolates a reaction space from an outer environment, and a door 130 through which a transfer device (not shown), which is for transferring a substrate 120 from the outside of the chamber into the chamber 110, may enter. The door 130 may be provided on a side of the chamber 110. A position or a size of the door 130 is not limited.

A gas inlet unit 140 is in an upper portion of the chamber 110, and a gas outlet unit 150 is in a lower portion of the chamber 110 and faces the gas inlet unit 140.

The gas inlet unit 140 may include a gas inlet opening (or hole) 141, and a shower head 142 connected to the gas inlet opening 141. A gas, which is a raw material for deposition, is injected into the chamber 110 through the gas inlet opening 141 from the outside of the chamber 110, and is sprayed (e.g., uniformly sprayed) to a film formation area A through the shower head 142.

The shower head 142 may include a plurality of spray openings (or holes) 143 that are arranged at regular intervals in a bottom surface of the shower head 142, and the spray openings 143 uniformly distribute a gas to the film formation area A, thereby improving uniformity of a thin film layer, for example, an organic layer, deposited on the substrate 120.

According to other embodiments of the present invention, the spray openings 143 of the shower head 142 may not be arranged at regular intervals, and/or the shower head 142 may not be provided.

The gas outlet unit 150 may be in the lower portion of the chamber 110 to face the gas inlet unit 140. The gas outlet unit 150 may include an exhaust opening (or hole) 151 through which a gas is discharged to the outside of the chamber 110, and a vacuum pump 152 that is connected to the exhaust opening 151 and maintains a suitable (or predetermined) degree of vacuum in the chamber 110.

As described above, because the gas inlet unit 140 and the gas outlet unit 150 are disposed in the upper and lower portions of the chamber 110 to face each other, airflow (e.g., a fine airflow) is formed from the upper portion of the chamber to the lower portion of the chamber in the chamber 110.

As long as the gas inlet unit 140 and the gas outlet unit 150 face each other, the gas inlet unit 140 and the gas outlet unit 150 may be arranged in various ways. In this case, the airflow formed in the chamber 110 may be formed in a direction in which the gas inlet unit 140 and the gas outlet unit 150 face each other.

A film formation unit 160 including an open mask 162 and a chuck 161, on which the substrate 120 is mounted, is between the gas inlet unit 140 and the gas outlet unit 150.

A thin film layer, such as an organic layer, is formed on the substrate 120 disposed on the chuck 161 when the supplied gases react with one another. When the open mask 162 is provided along an outer edge of the substrate 120 in order to uniformly deposit the thin film layer on the substrate 120, the thin film layer is formed within the open mask 162, and an area in which the thin film layer is formed is the film formation area A.

Although the film formation area A has a square shape in FIG. 2, embodiments are not limited thereto, and the film formation area A may have any of a variety of other shapes according to film formation purposes.

Because the chuck 161 on which the substrate 120 is mounted may include a heater (not shown) that supplies thermal energy to the substrate 120, and an elevation unit 163 that is disposed under the chuck 161 may vertically move the substrate 120, a space in which gases react may be adjusted by adjusting a space between the gas inlet unit 140 and the substrate 120.

The film formation unit 160 may be located (or disposed) in a direction perpendicular (or substantially perpendicular) to a direction in which the gas inlet unit 140 and the gas outlet unit 150 face each other in order to uniformly deposit the thin film layer, but the embodiments are not limited thereto.

When the film formation unit 160 is located (or disposed) in a direction perpendicular (or substantially perpendicular) to a direction in which the gas inlet unit 140 and the gas outlet unit 150 face each other, a gas sprayed from the shower head 142 may be uniformly sprayed to the substrate 120, a part of the gas sprayed to the substrate 120 may be subjected to a reaction and deposited on the substrate 120, and a part of the gas which is not deposited may be discharged to the outside of the chamber through the outlet unit 150 located (or disposed) in the lower portion of the chamber 110.

The thin film layer, such as an organic layer, may be deposited in a suitable (or desired) area on the substrate 120 by using the deposition process.

In this case, in order to prevent gas in the chamber 110 from forming a film in an undesired area of the chamber 110, e.g., an area other than the substrate 120, a deposition-preventing unit 170 is provided.

In order to remove a film formation layer formed on the deposition-preventing unit 170, after a film formation process is performed several times, the deposition-preventing unit 170 includes a first deposition-preventing plate 171, a second deposition-preventing plate 172, and a deformation unit 173 located (or disposed) between the first deposition-preventing plate 171 and the second deposition-preventing plate 172.

Each of the first deposition-preventing plate 171 and the second deposition-preventing plate 172 may be formed of an elastic material, for example, a thin metal plate. Each of the first deposition-preventing plate 171 and the second deposition-preventing plate 172 may be formed of any of a variety of other materials (e.g., materials other than a thin metal plate) as long as the material is an elastic material.

Although the first deposition-preventing plate 171 and the second deposition-preventing plate 172 is illustrated as having a cylindrical shape in the embodiment of FIG. 2, the first deposition-preventing plate 171 and the second deposition-preventing plate 172 may have any of a variety of other shapes according to its position in the chamber 110.

Although the deposition-preventing unit 170 is located (or disposed) between the chamber 110 and the film formation area A on the substrate 120 to surround the film formation area A, the embodiments are not limited thereto. The deposition-preventing unit 170 may be selectively formed in the chamber 110. For example, the deposition-preventing unit 170 may be provided on an inner wall of the chamber 110 to be flat.

The deformation unit 173 is provided between the first deposition-preventing plate 171 and the second deposition-preventing plate 172. The deformation unit 173 may include a material that is deformed due to external stress energy. For example, the deformation unit 173 may be formed of a shape-memory alloy, such as a titanium alloy. In one embodiment, the stress energy that deforms the deformation unit 173 is supplied via a heat source. The deformation unit 173 may have a wire shape.

Although the deformation unit 173 has been described as being formed of a shape-memory alloy having a wire shape (which may be between the first deposition-preventing plate 171 and the second deposition-preventing plate 172), the deformation unit 173 may be formed of any of a variety of other materials as long as the material is deformable due to an external stress energy.

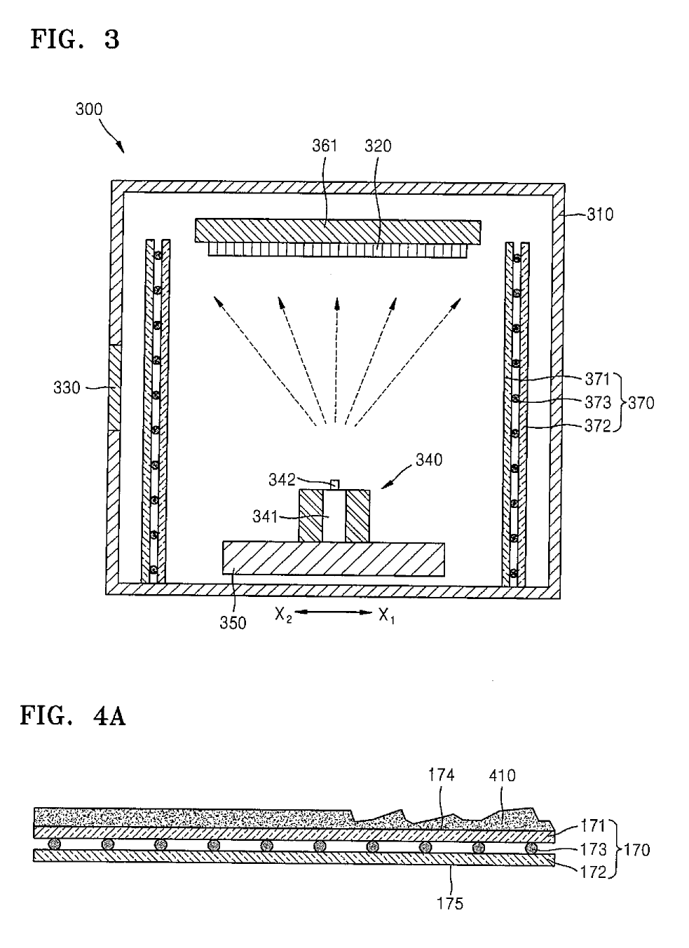

FIG. 3 is a cross-sectional view illustrating a thin film deposition device 300 according to another embodiment of the present invention.

Referring to FIG. 3, the thin film deposition device 300 includes a chamber 310. A door 330 through which a transfer device (not shown) for transferring a substrate 320 from the outside of the chamber into the chamber 310 enters may be provided on a side of the chamber 310.

A chuck 361 is disposed in an upper portion of the chamber 310. The substrate 320 is mounted on one surface of the chuck 361. After the substrate 320 is mounted on the chuck 361, a fixing unit (not shown) for fixing the substrate 320 to the chuck 361 may be used. The fixing unit may be any of a variety of types, such as a vacuum suction unit, a clamp, a pressure unit, or an adhesive material.

A deposition unit 340 is disposed in a lower portion of the chamber 310. The deposition unit 340 may include a crucible 341 and a nozzle 342. A raw material for deposition, for example, an organic raw material, is received in the crucible 341. A heating unit such as a heater (not shown) for heating the raw material for deposition may be disposed around the crucible 341.

The nozzle 342 is connected to the crucible 341 and provides a path through which the raw material for deposition flows. The raw material for deposition is evaporated to flow toward the substrate 320, thereby forming a thin film layer such as an organic layer on the substrate 320.

A driving unit 350 is connected to the deposition unit 340. The driving unit 350 moves the deposition unit 340, in a first direction (X₁ direction) or a second direction (X₂ direction), which are opposite to each other.

In one embodiment, the driving unit 350 may be connected to the substrate 320, to move the chuck 361 in the first direction (X₁ direction) or the second direction (X₂ direction).

In the thin film deposition device 300 constructed as described above, the raw material for deposition is deposited on the substrate 320 through the nozzle 342 to form a thin film layer on the substrate 320. For example, an organic monomer stored in the crucible 341 is sprayed from the crucible 341 through the nozzle 342 to the substrate 320. The organic monomer reaching the substrate 420 is cured, and thus, a thin film layer is formed on the substrate 320.

A deposition-preventing unit 370 is provided in order to prevent the raw material for deposition (which may scatter in the chamber 110) from forming a film in an area in the chamber 310 other than where the substrate 320 is located. In order to remove a film formation layer, e.g., an organic layer, formed on a surface of the deposition-preventing unit 370, the deposition-preventing unit 370 may include a first deposition-preventing plate 371, a second deposition-preventing plate 372, and a deformation unit 373 located (or disposed) between the first deposition-preventing plate 371 and the second deposition-preventing plate 372.

Each of the first deposition-preventing plate 371 and the second deposition-preventing plate 372 may be formed of an elastic metal plate, and the deformation unit 373 may have a wire shape and may be formed of a shape-memory alloy that is deformable due to an external stress energy.

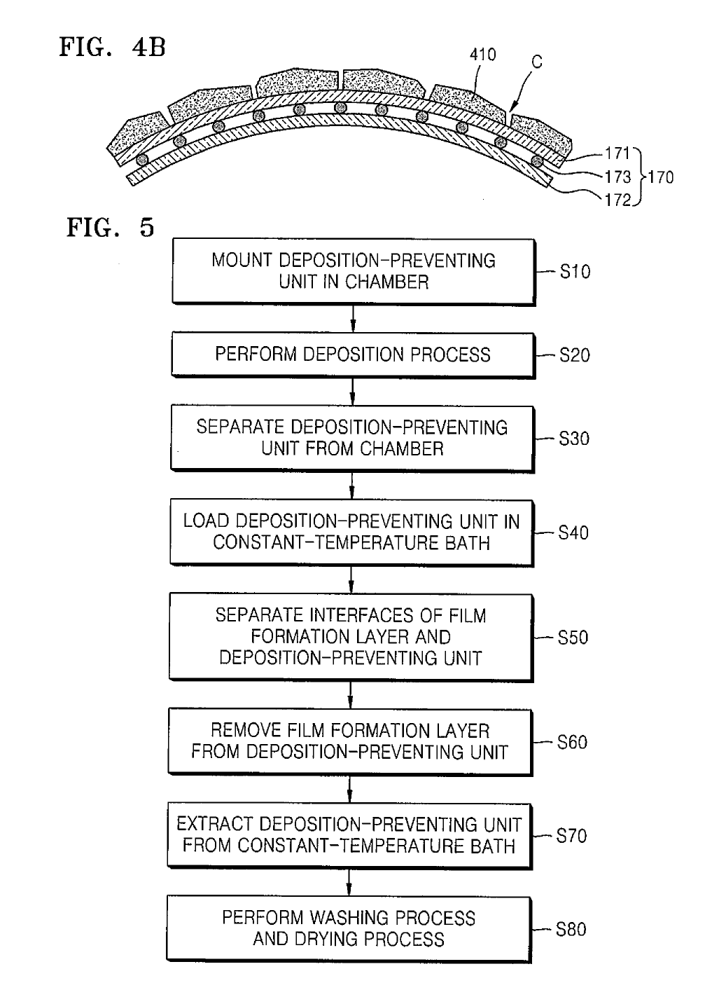

FIG. 4A is a cross-sectional view illustrating a state where a film formation layer is formed on the deposition-preventing unit 170 of FIG. 1. FIG. 4B is a cross-sectional view illustrating a state where the deposition-preventing unit 170 of FIG. 4A is deformed.

Referring to FIG. 4A, the deposition-preventing unit 170 includes the first deposition-preventing plate 171 and the second deposition-preventing plate 172 facing the first deposition-preventing plate 171.

A first surface 174 of the first deposition-preventing plate 171 is a surface on which a film is formed. A film formation layer 410 may form on the first surface 174. The film formation layer 410, which may be a liquid organic material including a curing agent, may be a film formation material that is formed on the first surface 174 to have a liquid organic phase at first, and is subjected to a subsequent process, for example, an ultraviolet curing process, to have a solid phase.

A second surface 175 of the second deposition-preventing plate 172, which is opposite to the first surface 174 of the first deposition-preventing plate 171, is a surface that may be connected to a surface to be protected or a wall in the chamber 110.

The deformation unit 173 is provided between the first deposition-preventing plate 171 and the second deposition-preventing plate 172. The deformation unit 173 may be formed of a shape-memory alloy, such as a titanium alloy, that is easily deformed due to external stress energy, such as that provided by a heat source.

The deformation unit 173 may have a wire shape. An outer circumferential surface of the deformation unit 173 contacts (e.g., directly contacts) the first deposition-preventing plate 171 and the second deposition-preventing plate 172.

In this case, the film formation layer 410 formed on the first surface 174 may form to a thickness of several millimeters while a deposition process is repeatedly performed, e.g., performed more than 1000 times. When the film formation layer 410 reaches a particular (or predefined) thickness, it may be desirable to remove the film formation layer 410. In one embodiment, because the first surface 174 of the first deposition-preventing plate 171 is a metal surface and the film formation layer 410 is formed of an organic material, the film formation layer 410 may be easily removed when external stress energy is applied to an adhesive force between the first surface 174 and the film formation layer 410.

Referring to FIG. 4B, external stress energy is applied to the deformation unit 173 between the first deposition-preventing plate 171 and the second deposition-preventing plate 172 to deform (e.g., instantly deform) the first surface 174 of the first deposition-preventing plate 171 and the second surface 175 of the second deposition-preventing plate 172, thereby easily removing the film formation layer 410 formed on the first surface 174.

For example, when stress energy is applied to the deformation unit 473, the deformation unit 173 may be bent in one direction (or otherwise deform). Accordingly, each of the first deposition-preventing plate 171 and the second deposition-preventing plate 172 contacting the outer circumferential surface of the deformation unit 173 may be deformed, thereby forming cracks C in the film formation layer 410.

Stress energy that deforms the deformation unit 173 may be provided via a heat source. Stress energy may be formed by applying ambient thermal energy to arrange internal energy of the deformation unit 173, and thus, the first deposition-preventing plate 171 and the second deposition-preventing plate 172 are deformed.

In order to return an original state after the deformation is completed, the heat source may be removed. As the heat source is removed, the stress energy of the deformation unit 173 is removed, and thus, each of the first deposition-preventing plate 171 and the second deposition-preventing plate 172 is restored to its original state. Accordingly, because the first deposition-preventing plate 171 and the second deposition-preventing plate 172 are elastically restored, the first deposition-preventing plate 171 and the second deposition-preventing plate 172 may be formed of an elastic material such as a metal plate.

Referring to FIG. 5, FIG. 5 is a flowchart illustrating a process of removing the film formation layer from the deposition-preventing unit.

A method of removing the film formation layer 410 from the deposition-preventing unit 170 will be explained using the thin film deposition device 100 of FIG. 1.

In operation S10, the deposition-preventing unit 170, including the first deposition-preventing plate 171, the second deposition-preventing plate 172, and the deformation unit 173 between the first deposition-preventing plate 171 and the second deposition-preventing plate 172, is mounted in the chamber 110. In operation S20, the substrate 120 is provided on the chuck 161 through the door 130 on a side of the chamber 110, and an organic deposition process (e.g., a high-speed organic deposition process) is performed on the substrate. A curing process may also be performed.

When the organic deposition process is repeatedly performed (e.g., performed hundreds of times to thousands of times), a thickness of the film formation layer 410 on the first surface 174 of the first deposition-preventing plate 171 is increased. In operation S30, when the thickness of the film formation layer 410 reaches a particular thickness (e.g., a several millimeters), the vacuum chamber 110 is maintained in an atmospheric pressure state, and the deposition-preventing unit 170 having a multi-step structure is separated from the chamber 110.

In operation S40, the deposition-preventing unit 170, on which the film formation layer 410 is formed, is loaded in a constant-temperature bath. In this case, the constant-temperature bath is maintained at a temperature equal to or higher than a temperature at which the deformation unit 173 deforms. In one embodiment, the constant-temperature bath is maintained at 120°.

According to one embodiment, when a temperature of the deposition-preventing unit 170 in the constant-temperature bath reaches a suitable temperature (e.g., 100°), the deformation unit 173 is deformed in one direction. For example, when the deformation unit 173 is deformed, the first deposition-preventing plate 171 and the second deposition-preventing plate 172, each contacting an outer circumferential surface of the deformation unit 173, are bent in the same direction.

In operation S50, when the first deposition-preventing plate 171 and the second deposition-preventing plate 172 are deformed, cracks C are formed in the film formation layer 410, which may be thickly formed on the first surface 174 of the first deposition-preventing plate 171, and interfaces of the film formation layer 410 and the first deposition-preventing plate 171 are separated from each other.

In operation S60, the film formation layer 410 formed on the first surface 174 of the first deposition-preventing plate 171 is removed, e.g., removed through a high-pressure gas purging process.

In operation S70, the constant-temperature bath is maintained at a suitable temperature (e.g., 30°), and when a temperature of the deposition-preventing unit 170 reaches a suitable temperature (e.g., 30°), the deposition-preventing unit 170 is extracted from the constant-temperature bath.

In operation S80, the film formation layer 410 may be completely removed from the deposition-preventing unit 170 by, for example, performing a washing process and a drying process in order to remove the film formation layer 410 still remaining due to, for example, a van der Waals force on the first surface 174 of the first deposition-preventing plate 171.

As described above, a film formation layer formed (e.g., thickly formed) on a surface of the deposition-preventing unit 170 may be easily removed from the deposition-preventing unit 170 without using chemical washing and physical surface treatment.

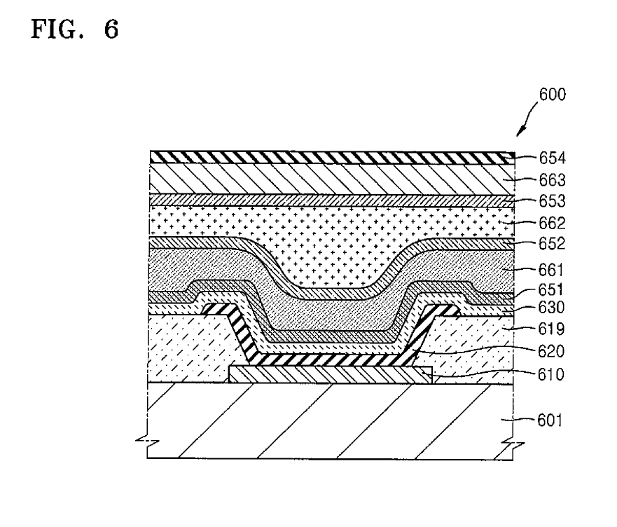

FIG. 6 is a cross-sectional view for explaining a method of manufacturing an organic light-emitting display device 600, according to an embodiment of the present invention.

A first electrode 610 that may act as an anode is formed on a substrate 601, and a pixel-defining film 619 may be formed on the first electrode 610. The pixel-defining film 619 may be formed not to cover at least one area of a top surface of the first electrode 610.

An organic light-emitting layer 620 may be formed on the first electrode 610.

A second electrode 630 that may act as a cathode may be formed on the organic light-emitting layer 620.

A first inorganic encapsulation layer 651, a first organic encapsulation layer 661, a second inorganic encapsulation layer 652, a second organic encapsulation layer 662, a third inorganic encapsulation layer 653, a third organic encapsulation layer 663, and a fourth inorganic encapsulation layer 654 may be formed on the second electrode 630. Although not shown in FIG. 6, a buffer layer may be formed on the second electrode 630 and the first inorganic encapsulation layer 651.

In detail, the first inorganic encapsulation layer 651 may be formed on the second electrode 630. The first organic encapsulation layer 661 may be formed on the first inorganic encapsulation layer 651 by using the deposition device 100 or 300 of FIG. 1 or 3.

Accordingly, an impurity material such as an organic material is prevented from being introduced from an organic monomer to the organic light-emitting layer 620, particularly, a surface of the organic light-emitting layer 620 not covered by the second electrode 630 and the first inorganic encapsulation layer 651.

The organic light-emitting display device 600 effectively protects the organic light-emitting layer 620, the first electrode 610, and the second electrode 630 by using a stacked structure in which inorganic encapsulation layers and organic encapsulation layers are stacked on the second electrode 630.

As described above, a thin film deposition device including a deposition-preventing unit and a method of removing deposits thereof according to the present invention may easily remove a film formation layer formed on the deposition-preventing unit by using a multi-step deposition-preventing structure including a deformation unit.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

What is claimed is:

1. A thin film deposition device comprising:
a chamber;
a deposition unit in the chamber configured to deposit a raw material on a substrate; and
a deposition-preventing unit in the chamber comprising at least one deposition-preventing plate and a deformation unit coupled to one surface of the deposition-preventing plate.

2. The thin film deposition device of claim 1, wherein the at least one deposition-preventing plate comprises a metal plate.

3. The thin film deposition device of claim 1, wherein the deformation unit comprises a shape-memory alloy.

4. The thin film deposition device of claim 1, wherein the deformation unit has a wire shape and contacts the one surface of the deposition-preventing plate.

5. The thin film deposition device of claim 1,
wherein the at least one deposition-preventing plate comprises a first deposition-preventing plate and a second deposition-preventing plate, and
wherein the deformation unit is between facing surfaces of the first deposition-preventing plate and the second deposition-preventing plate.

6. The thin film deposition device of claim 5, wherein the deformation unit has a wire shape.

7. The thin film deposition device of claim 5, wherein an outer surface of the deformation unit contacts the facing surfaces of the first deposition-preventing plate and the second deposition-preventing plate.

8. The thin film deposition device of claim 1, wherein the deposition-preventing unit is between the chamber and a film formation area where a film formation layer is to be formed.

9. A method of removing deposits of a thin film deposition device, the method comprising:
separating a deposition-preventing unit comprising at least one deposition-preventing plate and a deformation unit coupled to an outer surface of the at least one deposition-preventing plate from a chamber of the thin film deposition device; and
removing a film formation layer from the deposition-preventing plate.

10. The method of claim 9,
wherein the at least one deposition-preventing plate comprises a first deposition-preventing plate and a second deposition-preventing plate, and
wherein the deformation unit is between facing surfaces of the first deposition-preventing plate and the second deposition-preventing plate.

11. The method of claim 10, wherein the deformation unit comprises a shape-memory alloy.

12. The method of claim 11, wherein the deformation unit has a wire shape, and an outer surface of the deformation unit contacts the facing surfaces of the first deposition-preventing plate and the second deposition-preventing plate.

13. The method of claim 9, wherein the removing of the film formation layer from the deposition-preventing plate comprises:
loading the deposition-preventing unit in a constant-temperature bath;
separating interfaces between portions of the film formation layer and the deposition-preventing unit;
removing the film formation layer from the deposition-preventing unit by using a gas purging process; and
extracting the deposition-preventing unit from the constant-temperature bath.

14. The method of claim 13, wherein the constant-temperature bath is maintained at a temperature equal to or higher than a temperature at which the deformation unit is deformed.

15. The method of claim 13, further comprising performing a washing process and a drying process after the extracting of the deposition-preventing unit.

16. The method of claim 1, further comprising:
mounting the deposition-preventing unit in the chamber; and
depositing a raw material for deposition on a substrate from a deposition unit provided in the chamber.
